(19) United States
(12) Patent Application Publication
(10) Pub. No.: US 2007/0245213 A1
(43) Pub. Date: Oct. 18, 2007

(54) Reproduction device and reproducing method

(75) Inventor: Yuji Yoshida, Kasugai (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/542,137

(22) Filed: Oct. 4, 2006

(30) Foreign Application Priority Data
Mar. 23, 2006 (JP) 2006-080662

(51) Int. Cl. H03M 13/00

(52) U.S. Cl. 714/758

(57) ABSTRACT

A reproduction device for improving reading performance. A storage processing unit includes a detection circuit for detecting a sync code from read data, which includes alternately arranged sync codes and data segments. An analysis circuit analyzes a read status of the sync code detected by the detection circuit. A storage processing circuit adjusts a position at which one of the data segments between two sync codes is stored in a main memory based on the analysis of the analysis circuit.

### CROSS-REFERENCE TO RELATED APPLICATIONS

This application is based upon and claims the benefit of priority from the prior Japanese Patent Application No. 2006-080662, filed on Mar. 23, 2006, the entire contents of which are incorporated herein by reference.

### BACKGROUND OF THE INVENTION

The present invention relates to a reproduction device and a reproducing method, and more particularly, to a device and method for reading information recorded on an optical recording medium.

An optical disc is a recording media for recording information with high density. Information is optically read (reproduced) from the optical disc. When a blemish or smear is on the surface of the optical disc, data cannot be accurately read from the optical disc. Further, when the optical disc rotates irregularly during data reading, the amount of data recorded on the disk may differ from the amount of data generated by processing reflection light from the disk. Accordingly, in addition to user data, code information (correction code) for correcting the read data (error correction) is recorded on the optical disc. However, the read data may not be corrected depending on the condition of the read data. Thus, there is a demand for improvements in reading performance of the optical disc.

In the prior art, to improve the reading performance, a correction code calculated for every predetermined amount of user data is recorded on an optical disc, such as a digital video disk or digital versatile disk (DVD). As shown in FIG. 1, a data block BD recorded on an optical disc includes a predetermined amount of user data UD (172 bytes×192 rows (12 rows×16 sectors)), a ten-byte correction code PI for each row of the user data UD calculated from the data in the column direction of the user data UD (B(x, 0) to B(x, 171)), and a sixteen-byte correction code PO (B(192, y) to B(207, y)) for each column calculated from the correction code PI and data in the row direction of the user data UD (B(0, y) to B(191, y)). Some of the correction codes PO are also used as the correction codes PI. The correction codes PI and the correction codes PO are used in error correction (processing for identifying a data error position and calculating a correction value) performed when data is read from the optical disc. The data arrangement sequence (order) of the data block BD is important in the error correction.

In the error correction, each row and column of the data block BD is processed as a codeword, and each column and row undergoes the error correction. More specifically, one data block BD is processed as 208 data rows H0 to H207 or as 182 data columns V0 to V181 as shown in FIG. 1. Errors are corrected in the user data UD and the correction code data PO for each of the data rows H0 to H207 using the user data UD or the correction code data PO and the correction code data PI. Further, errors are corrected in the user data UD and the correction data PO for each of the data columns V0 to V181 using the user data UD or the correction code data PI and the correction code data PO.

As shown in FIG. 2, each of the data rows H192 to H207 for the correction codes PO in the data block BD is inserted (interleaved) between every twelve data rows of the user data UD. One recording sector is constructed by the twelve rows of the user data UD and one row of the correction code data PO. As a result, one data block BD includes sixteen recording sectors C0 to C15.

Data included in the data block BD undergoes eight-to-sixteen modulation. More specifically, eight bits of data, or one byte, is modulated into data having sixteen channel bits (cb). As shown in FIG. 3, one of eight synchronization (sync) codes SY0 to SY7 is added to every 91 bytes (1456 cb) of modulation data. Each sync code has two bytes (32 cb). One sync frame is formed by the 91-byte modulation data and the 2-byte sync code. The sync codes are added to the modulation data in a predetermined order. The sync codes enable identification of the modulation data that is currently being read. The data shown in FIG. 3 is recorded to an optical disc sequentially from the top left. Data is read from the optical disc in the order starting from the top left FIG. 3.

When data is correctly read from the optical disc, a processing circuit receives the read data as a plurality of data segments divided by sync codes as shown in FIG. 4. The processing circuit stores the data segment between two sync codes in a memory 100. When the each data segment reaches 91 bytes, a data block BD (FIG. 1) recorded on the optical disc is stored in the memory. Thus, error correction is accurately performed on the user data with the correction code data PI and the correction code data PO.

### SUMMARY OF THE INVENTION

A blemish or smear on the surface of the disc or irregular rotation of the disc may result in loss of a sync code or some of the user data. This may also produce excessive data. For example, referring to FIG. 5, when two bytes of data between two sync codes SY5 are missing, the processing circuit stores 91 bytes of data segment (D1) following the former one of the two sync codes SY5 in the memory 100. Then, the processing circuit processes the following two bytes as a sync code and stores the 89 bytes of data segment (D2) following that sync code in the memory 100. When the missing two bytes correspond to the sync code SY1 shown in FIG. 4, the data segment D2 is stored in the memory 100 at a position deviating by two bytes from its correct storage position. Thus, each value in the data segment D2 is processed as an error when the error correction is performed in the direction of the correction code PO. In other words, 91 bytes of data segment are determined as being defective. Such defective data may not be corrected depending on the position or amount of the defective data. In such a case, the entire data block BD is determined as being defective. This lowers the reading performance of the optical disc.

The present invention provides a reproduction device and a reproducing method for improving the data reading performance.

One aspect of the present invention is a reproduction device for retrieving read data including a plurality of sync codes and a plurality of data segments, which are arranged alternately with the sync codes, and storing the data segments in a first memory in accordance with the sync codes. The reproduction device includes a detection circuit for detecting each of the sync codes from the read data to generate a detection signal. An analysis circuit, connected to the detection circuit, analyzes a read status of each of the sync codes with the read data and the detection signal to generate an analysis signal. A storage processing circuit, connected to the analysis circuit, retrieves one of the data segments between two sync codes with the read data and the analysis signal and adjusts a position at which the one of the data segments is stored in the first memory.

A further aspect of the present invention is a method for retrieving read data including a plurality of sync codes and a plurality of data segments, which are arranged alternately with the sync codes, with a reproduction device and storing the data segments in a first memory in accordance with the sync codes. The method includes detecting each of the sync codes from the read data to generate a detection signal, generating an analysis signal by analyzing a read status of each of the sync codes with the read data and the detection signal, and retrieving one of the data segments between two sync codes with the read data and the analysis signal and adjusting a position at which the one of the data segments is stored in the first memory.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic diagram showing the data structure of a data block including user data and error correction codes;

FIG. 2 is a schematic diagram showing the data structure of recording sectors in a DVD;

FIG. 3 is a schematic diagram showing the data structure of data recorded on a DVD;

FIG. 4 is a schematic diagram showing a data reading operation in the prior art;

FIG. 5 is a schematic diagram showing a data reading operation in the prior art;

FIG. 6 is a schematic block diagram of a reproduction device according to a preferred embodiment of the present invention;

FIG. 7 is a schematic block diagram of a storage processing circuit shown in FIG. 6;

FIG. 8 is a schematic flowchart of the operation of an analysis circuit shown in FIG. 7;

FIG. 9(a) is a flowchart showing the operation of the storage processing circuit of FIG. 7;

FIG. 9(b) is a schematic diagram showing step 61 of FIG. 9(a);

FIG. 10(a) is a schematic diagram showing data reading performed by the storage processing circuit of FIG. 7;

FIG. 10(b) is a schematic diagram showing data reading performed by the storage processing circuit of FIG. 7;

FIG. 10(c) is a schematic diagram showing data reading performed by the storage processing circuit of FIG. 7;

FIG. 10(d) is a schematic diagram showing data reading performed by the storage processing circuit of FIG. 7;

FIG. 11(a) is a schematic diagram showing data reading performed by the storage processing circuit of FIG. 7;

FIG. 11(b) is a schematic diagram showing data reading performed by the storage processing circuit of FIG. 7;

FIG. 11(c) is a schematic diagram showing data reading performed by the storage processing circuit of FIG. 7;

FIG. 11(d) is a schematic diagram showing data reading performed by the storage processing circuit of FIG. 7; and

FIG. 12 is a schematic diagram showing a data storage process performed by the storage processing circuit of FIG. 7.

### DETAILED DESCRIPTION OF THE PREFERRED EMBODIMENTS

In the drawings, like numeral are used for like elements throughout.

A reproduction device 10 according to a preferred embodiment of the present invention will now be described with reference to the drawings.

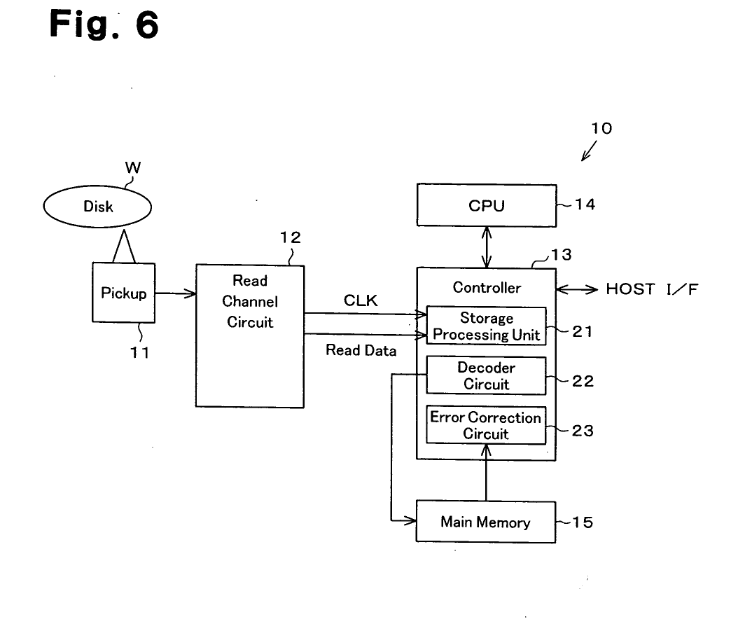

FIG. 6 is a schematic block diagram of the reproduction device 10.

The reproduction device 10 reads data recorded on an optical disc W, which functions as a recording medium.

The disc W is rotated by a drive device (not shown). A pickup 11 is arranged to face the disc W. The pickup 11 is moved by a drive device (not shown) in the radial direction of the disc W. The pickup 11 radiates the disc W with light having a predetermined wavelength and converts reflection light from the disc W into an electric signal to generate an output signal. A read channel circuit 12 converts the output signal of the pickup 11 to binary data to generate a data signal (read data) and provides a controller 13 with the read data. The controller 13 is controlled by a CPU 14.

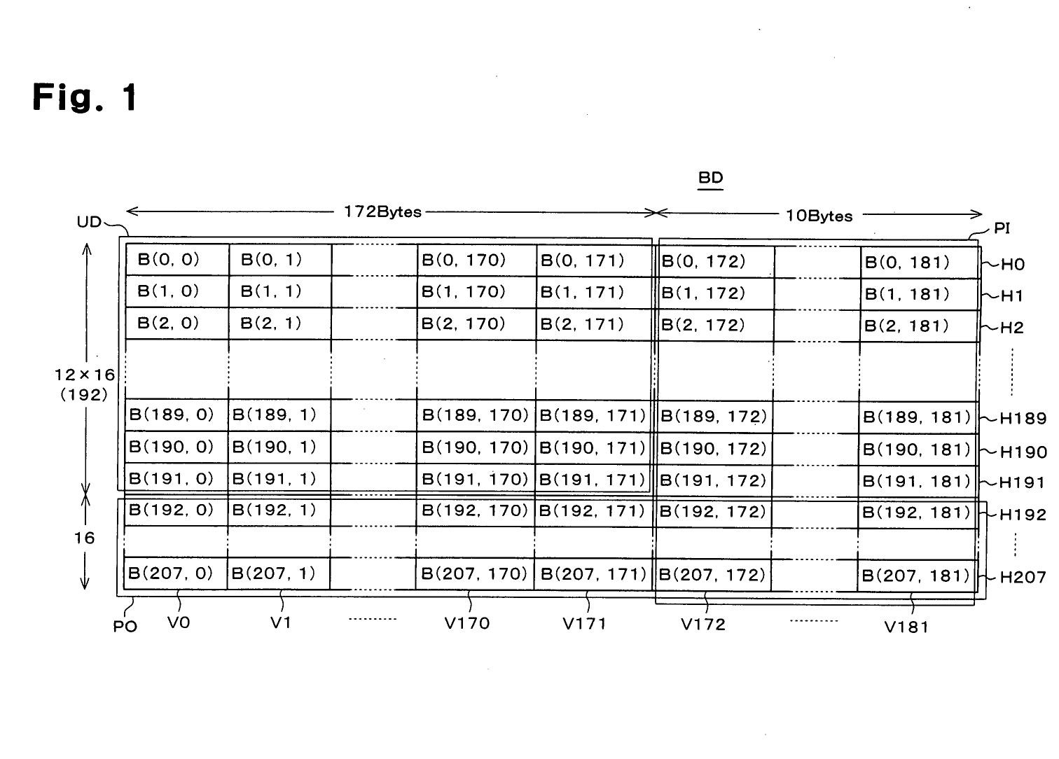

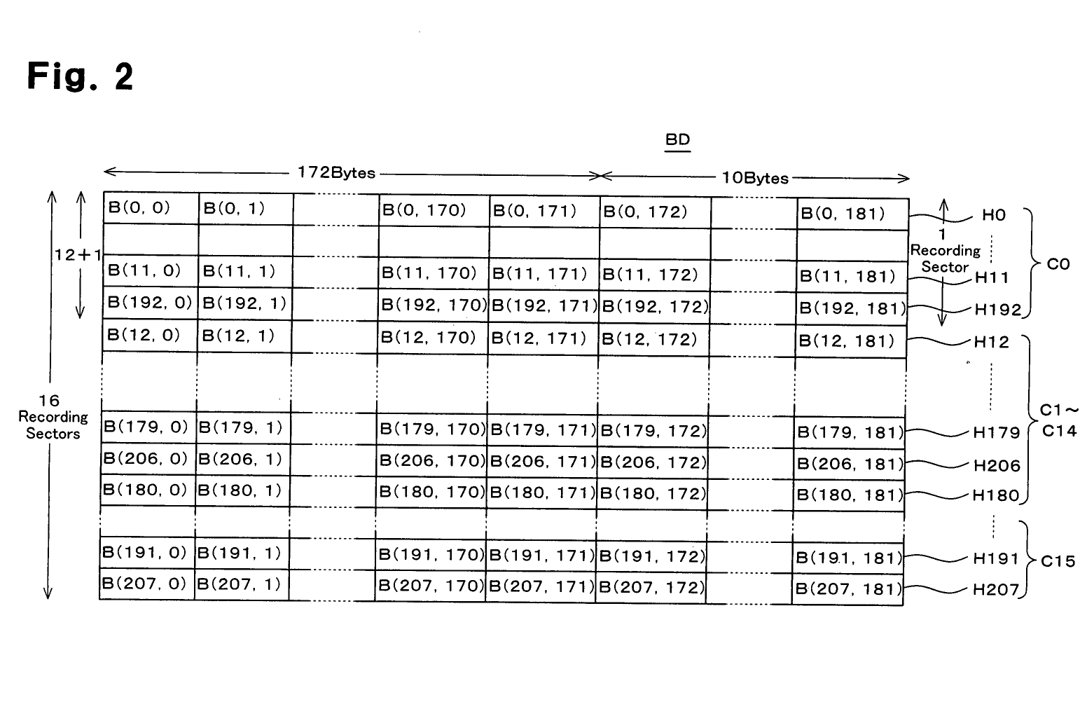

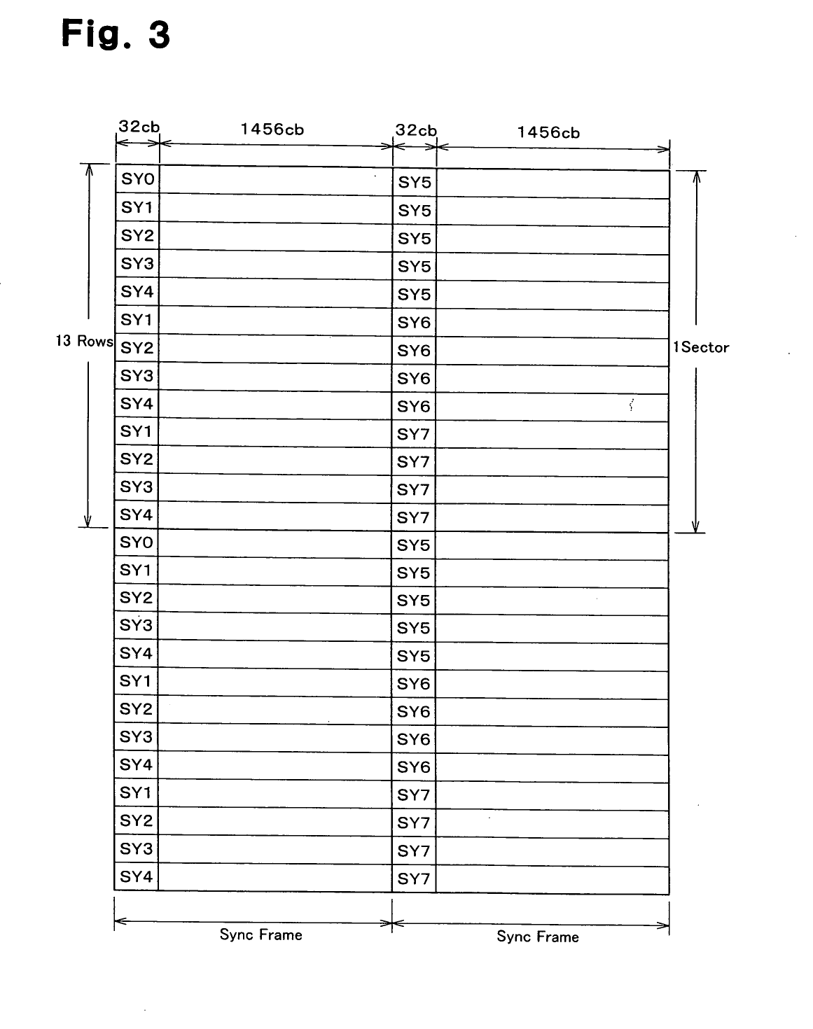

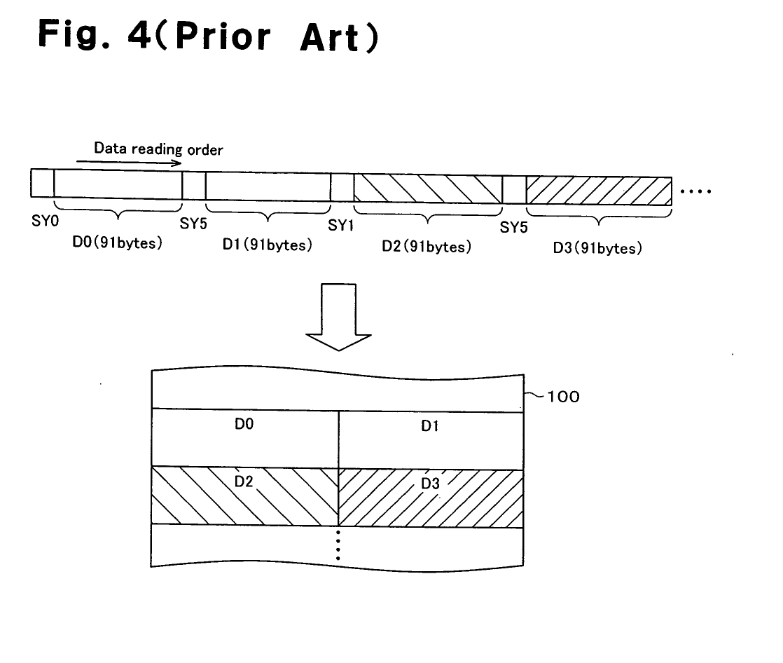

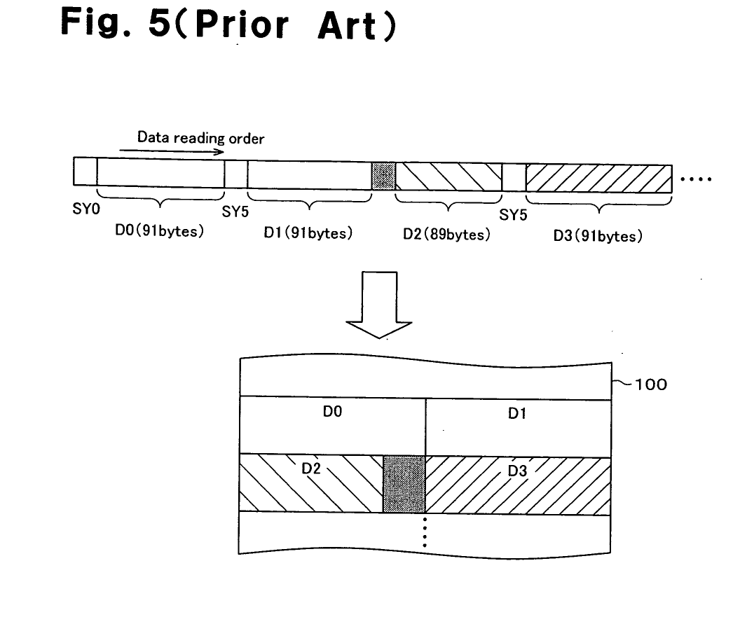

In the preferred embodiment, the read data includes a plurality of sync codes and modulation data. The modulation data is divided into a plurality of data segments. The sync codes and the data segments are arranged alternately. Each sync code corresponds to one of the eight sync codes SY0 to SY7 shown in FIG. 3. Each data segment has 91 bytes (1456 cb) as shown in FIG. 3. The Each data segment is generated by modulating the data block BD shown in FIG. 1 (including the user data UD, the first correction codes PI, and the second correction codes PO).

The controller 13 includes a storage processing unit 21, a decoder circuit 22, and an error correction circuit 23. The controller 13 retrieves the data segments based on the read data provided from a read channel circuit 12 and stores the retrieved data segments into a main memory 15 (a first memory). The controller 13 then performs error correction on a single block of data stored in the main memory 15 and provides a host apparatus (not shown) with the user data.

The storage processing unit 21 detects a sync code from the read data. Based on the detection, the storage processing unit 21 adjusts the storage position of the data segment stored in the main memory 15 and generates adjustment data. In detail, the storage processing unit 21 analyzes the read status of the detected sync code. Based on the analysis, the storage processing unit 21 determines how to store the data segment that has been read before detection of the sync code. In accordance with the determination, the storage processing unit 21 generates the adjustment data from the read data. For example, when determining from the read status of the sync code that the head of the data segment that is to be stored in the main memory 15 is missing, the storage processing unit 21 adds dummy data to the data segment head. The amount of the dummy data is equal to the amount of the missing data. This prevents the entire data from being stored at erroneous positions and increases the amount of data stored at correct positions. In other words, the amount of data that needs correction decreases. Thus, the error correction accuracy is increased, and the data reading performance is improved.

The decoder circuit 22 generates demodulation data by performing eight-to-sixteen demodulation on the data segment of which storage position has been adjusted by the storage processing unit 21 and stores the demodulation data in the main memory 15. The storage processing unit 21 adjusts the position for storing the data provided to the decoder circuit 22. This stores a specified amount of data at correct positions in the memory 15.

The error correction circuit 23 performs error correction on a single block of data stored in the main memory 15. The error correction circuit 23 determines the position and correction value of a data error with the correction code data PI and the correction code data PO added to the user data UD and rewrites the erroneous data in the main memory 15. For example, referring to FIG. 1, the first two bytes of data row H0 for one sync frame may be missing. In this case, with the prior art technique, the correctly received 180 bytes of data is sequentially stored from the left end, and predetermined data (e.g., “0”) is stored in the area for two bytes at the right end. In this case, the entire data row H0 is processed as an error. In the preferred embodiment of the present invention, the storage position of the missing data is adjusted. For example, the storage positions of the 180 bytes of data of the data row H0 are determined by aligning the end of the data with the right end of the storage area. In this case, only the first two bytes of data are processed as an error. More specifically, the amount of error data is 182 bytes in the prior art, whereas the amount of error data is reduced to two bytes in the preferred embodiment. This improves the data reading performance.

The structure of the storage processing unit 21 will now be described.

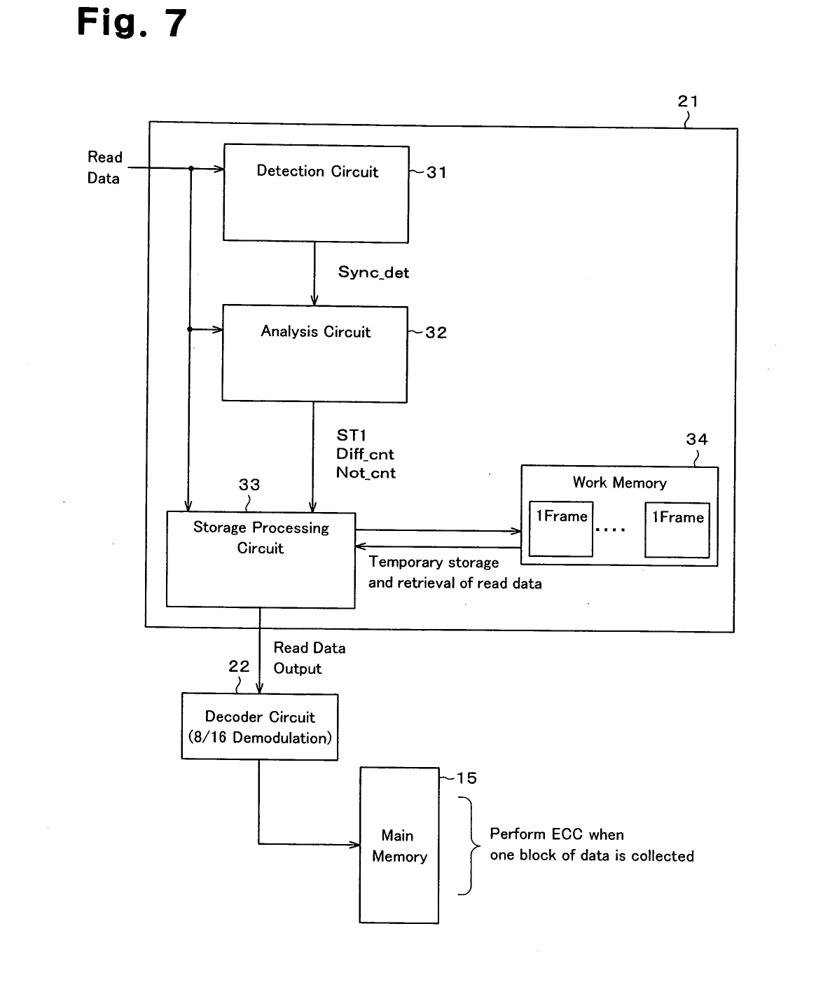

As shown in FIG. 7, the storage processing unit 21 includes a detection circuit 31, an analysis circuit 32, a storage processing circuit 33, and a work memory 34 (second memory). The detection circuit 31 detects a sync code from the read data and generates a detection signal Sync_det. The analysis circuit 32 analyzes the read status of the detected sync code based on the read data and the detection signal Sync_det to generate an analysis signal. The position of the sync code is predetermined by a standard. The standard specifies that 91 bytes of data segment are arranged between two sync codes. The read data is generated through eight-to-sixteen modulation and has 16 channel bits (cb). Each sync code has two bytes (32 cb).

The analysis circuit 32 analyzes the read status of a sync code based on the number of bytes of the read data between two sync codes. For example, when the detection circuit 31 detects a first sync code, the analysis circuit 32 starts counting the number of bytes of the data following the first sync code. Then, when the detection circuit 31 detects a second sync code, the analysis circuit 32 determines whether the count value of the read data between the first and second sync codes is equal to a predetermined value (91 bytes). When the count value is equal to the predetermined value, the analysis circuit 32 determines that the second sync code has been detected at an expected position. In other words, the analysis circuit 32 determines that the data segment has 91 bytes between the first and second sync codes. When the count value is not equal to the predetermined value, the analysis circuit 32 determines that part of the data segment is missing, a sync code is missing between the detected first and second sync codes, or that excessive data is included between the first and second sync codes. In this way, the analysis circuit 32 analyzes the read status of the second sync code. The storage processing circuit 33 adjusts the storage position of the read data in the main memory 15 in accordance with the read status of the sync code analyzed by the analysis circuit 32. As a result, the read data is stored at the correct positions.

The analysis circuit 32 generates a status ST1 (analysis signal), a position difference Diff_cnt, and a code non-detection count Not_cnt. The position difference Diff_cnt and the code non-detection count Not_cnt indicate count values of predetermined counters. The status ST1 indicates the read status of a sync code, which are classified as a first status (SY_OK), a second status (SYShift_more), a third status (SYShift_less), and a fourth status (SY_NOT). The first status means indicates that a sync code has been detected at its expected position (position determined by the standard). The second status indicates that a sync code has been detected behind an expected position of the sync code. The third status indicates that a sync code has been detected in front of an expected position of the sync code. The fourth status indicates that a sync code has not been detected in a predetermined detection range including the expected position of the sync code, or in the frame that is currently being read. The position difference Diff_cnt indicates the difference (in byte number) between an expected position and actual detection position of a sync code. The code non-detection count Not_cnt indicates the number of frames in which a sync code has not been detected.

The storage processing circuit 33 stores read data in the work memory 34. The work memory 34 has a capacity enabling storage of plural frames of read data. Each frame corresponds to a sync frame (refer to FIG. 3) having 93 bytes, which includes a sync code (two bytes) and data segment (91 bytes).

The storage processing circuit 33 retrieves data segment from the work memory 34 based on the analysis signal and adjusts the storage position of the data segment that is to be stored in the memory 15 to generate adjustment data. As one example, when the status ST1 indicates the first status, the storage processing circuit 33 directly uses one frame of the data segment in the work memory 34 as one frame of adjustment data. As another example, when the status ST1 indicates the third status, the storage processing circuit 33 adds dummy data to the head of the data segment in the work memory 34 that has less bytes than one frame to adjust the storage position of the data segment stored in the memory 15 and generate one frame of adjustment data. The dummy data is, for example, “0” data added by performing zero padding. The storage processing circuit 33 performs zero padding to add “0” for the number of bytes corresponding to the position difference Diff_cnt to the data segment stored in the work memory 34. The storage processing circuit 33 then adjusts the storage position of the data segment stored in the main memory 15 so that the number of bytes of the data segment stored in the work memory 34 and the number of bytes of the dummy data total to become equal to the number of bytes for one frame.

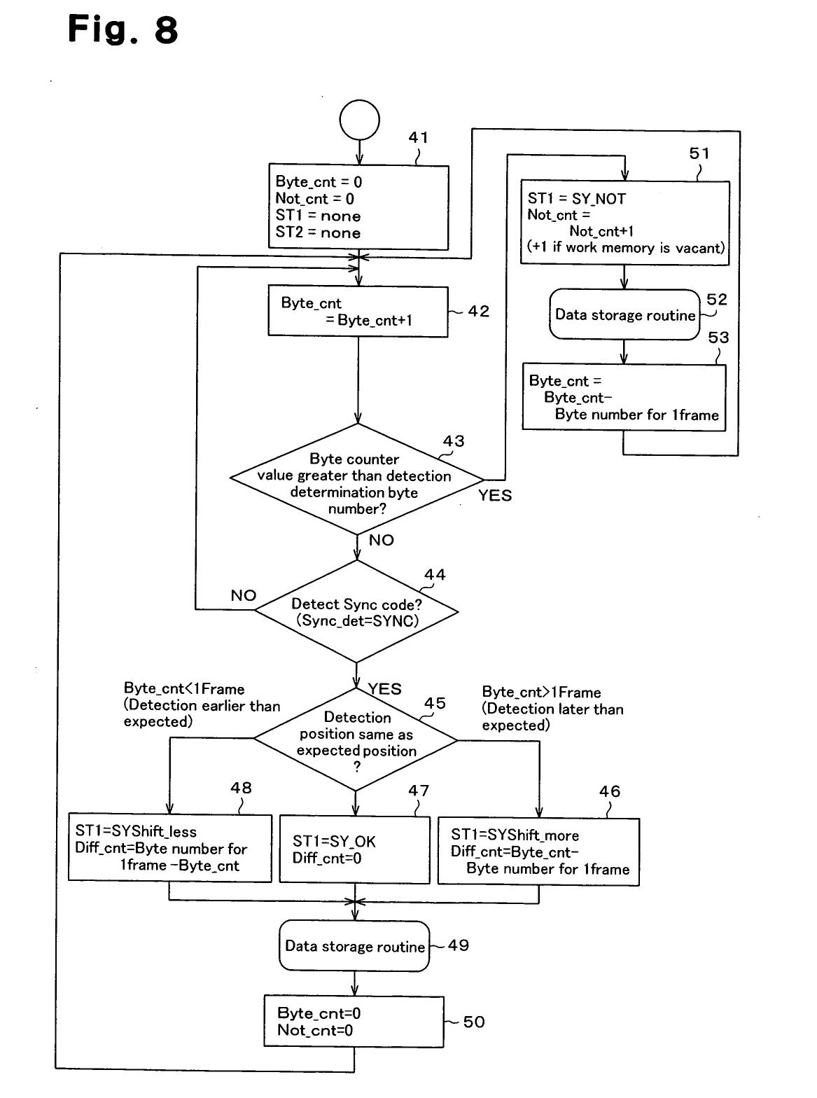

FIG. 8 is a flowchart schematically illustrating the operation of the analysis circuit 32 shown in FIG. 7.

In step 41, the analysis circuit 32 performs an initialization process. In the initialization process, the analysis circuit 32 clears (sets to zero) the byte count Byte_cnt and the code non-detection count Not_cnt for each frame and sets each of status ST1 and previous status ST2 to an initial state (none). The previous status ST2 indicates the status immediately preceding the status ST1.

In step 42, the analysis circuit 32 counts up (+1) the byte count Byte_cnt when provided with one byte of read data. In step 43, the analysis circuit 32 determines whether the byte count Byte_cnt exceeds a detection determination byte number (sum of number of bytes for one frame and number of bytes for determining code non-detection). The code non-detection determination byte number corresponds to a detection range (byte number) in which a sync code is expected to be detected. The analysis circuit 32 detects a sync code from read data within a detection range that extends from an expected position of the sync code to a position separated from the expected position by the code non-detection determination byte number. When the byte count Byte_cnt does not exceed the detection determination byte number (NO), the analysis circuit 32 proceeds to step 44.

In step 44, the analysis circuit 32 determines whether a sync code (SYNC) has been detected based on a detection signal Sync_det. The analysis circuit 32 proceeds to step 45 when a sync code is detected (YES) and proceeds to step 42 when a sync code is not detected (NO).

In step 45, the analysis circuit 32 determines whether the detection position of the sync code is the same as the expected position based on the byte count Byte_cnt. The analysis circuit 32 proceeds to step 46 when the byte count Byte_cnt is greater than the number of bytes of one frame (Byte_cnt>the number of bytes of one frame). The analysis circuit 32 proceeds to step 47 when the byte count Byte_cnt is equal to the number of bytes of one frame (Byte_cnt=the number of bytes of one frame). The analysis circuit 32 proceeds to step 48 when the byte count Byte_cnt is less than the number of bytes of one frame (Byte_cnt<the number of bytes of one frame).

In step 46, the analysis circuit 32 changes the status ST1 to indicate the second status (SYShift_more), subtracts the number of bytes of one frame from the byte count Byte_cnt, and sets the value indicating the subtraction result as the position difference Diff_cnt.

In step 47, the analysis circuit 32 changes the status ST1 to indicate the first status (SY_OK) and clears the position difference Diff_cnt (=0).

In step 48, the analysis circuit 32 changes the status ST1 to indicate the third status (SYShift_less), subtracts the byte count Byte_cnt from the number of bytes of one frame, and sets the value indicating the subtraction result as the position difference Diff_cnt.

When the processing of steps 46, 47, or 48 is completed, the analysis circuit 32 proceeds to step 49. In step 49, the analysis circuit 32 instructs the storage processing circuit 33 to start a data storage process. In step 50, the analysis circuit 32 clears the byte count Byte_cnt and the code non-detection count Not_cnt and proceeds to step 42.

In step 43 described above, when the byte count Byte_cnt exceeds the detection determination byte number (YES), the analysis circuit 32 proceeds to step 51.

In step 51, the analysis circuit 32 changes the status ST1 to indicate the fourth status (SY_NOT). Further, the analysis circuit 32 counts up (+1) the code non-detection count Not_cnt if the work memory 34 has a vacant area. In step 52, the analysis circuit 32 instructs the storage processing circuit 33 to start the data storage process. Next, in step 53, the analysis circuit 32 subtracts the number of bytes of one frame from the byte count Byte_cnt and sets the value indicating the subtraction result as the byte count Byte_cnt. The analysis circuit 32 then proceeds to step 42.

The operation of the storage processing circuit 33 will now be described.

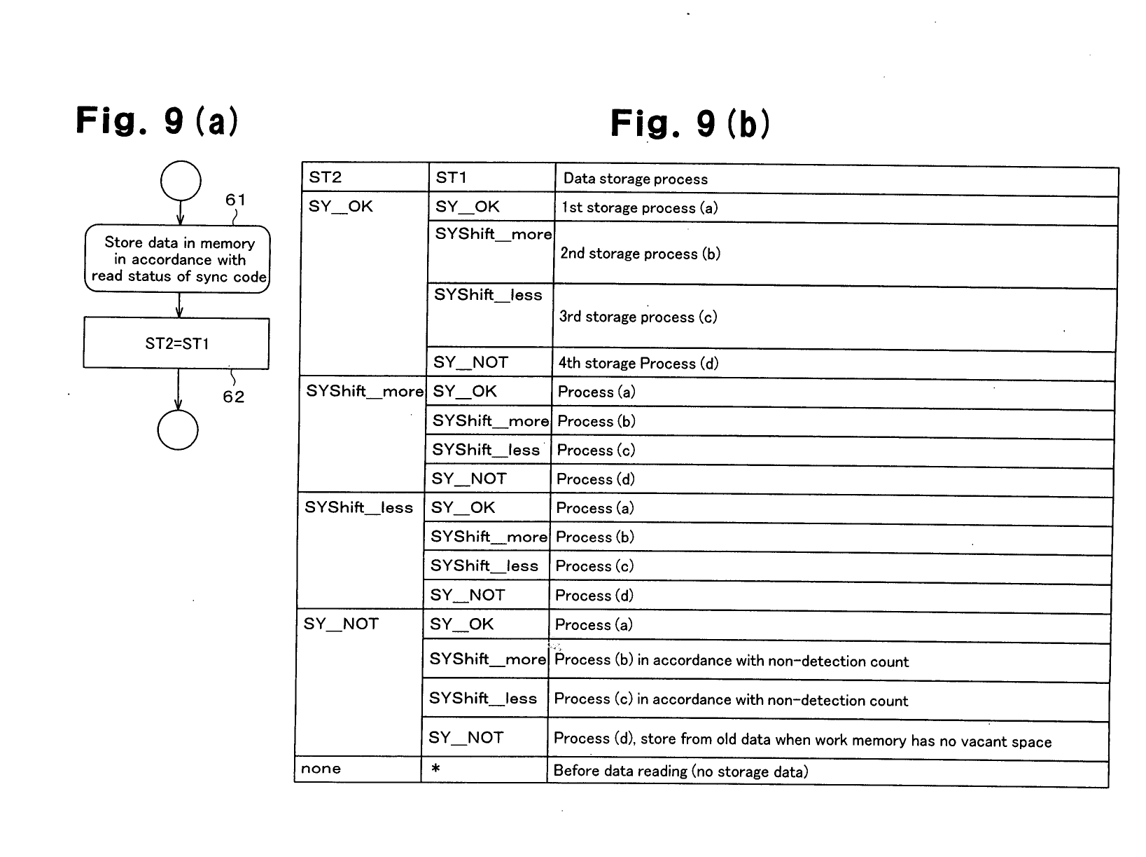

FIG. 9(a) is a schematic flowchart illustrating the operation of the storage processing circuit 33 shown in FIG. 7. FIG. 9(b) is a schematic diagram showing the processing of step 61 in FIG. 9(a).

In step 61, the storage processing circuit 33 receives an analysis signal from the analysis circuit 32, and stores data (data segment) in the main memory 15 via the decoder circuit 22 in accordance with the current status ST1 included in the received analysis signal and the previous status ST2.

The processing of step 61 performed when the previous status ST2 indicates the first status (SY_OK) will now be discussed.

When the current status ST1 indicates the first status (SY_OK), the storage processing circuit 33 executes a first data storage process (a). In the first status, exactly one frame (91 bytes) of read data is stored in the work memory 34. Thus, the storage processing circuit 33 directly stores the one frame of read data corresponding stored in the work memory 34 at predetermined addresses in a memory space.

When the current status ST1 indicates the second status (SYShift_more), the storage processing circuit 33 executes a second data storage process (b). In the second status, read data having more bytes than one frame is stored in the work memory 34. The storage processing circuit 33 stores a predetermined amount (one frame of) read data in the main memory 15 through one of the following processes (A1), (A2), and (A3), preferably process (A3) and deletes an excessive data exceeding the predetermined amount.

(A1) The storage processing circuit 33 stores the read data in the main memory 15 sequentially from the data end, which is adjacent to the current sync code. When doing so, the storage processing circuit 33 sequentially stores the read data from the final address of the predetermined memory space.

(A2) The storage processing circuit 33 sequentially stores the read data in the main memory 15 from the data head, which is adjacent to the preceding sync code. When doing so, the storage processing circuit 33 stores the read data from the first address of the predetermined memory space.

(A3) The storage processing circuit 33 stores the read data in the main memory 15 using both processes (A1) and (A2). More specifically, when storing the read data between the two sync codes, the storage processing circuit 33 stores the head portion of the read data from the first address of the predetermined memory space and stores the final portion of the read data from the final address of the predetermined memory address.

When the current status ST1 indicates the third status (SYShift_less), the storage processing circuit 33 executes a third data storage process (c). In the third status, read data having bytes less than one frame is stored in the work memory 34. In the third data storage process (c), the storage processing circuit 33 stores the read data in the memory 15 through one of processes (A1), (A2), and (A3) described above, preferably through process (A3), and performs zero padding to compensate for the missing data. As a result, data having the predetermined number of bytes (corresponding to one frame) is stored in the main memory 15.

When the current status ST1 indicates the fourth status (SY_NOT), the storage processing circuit 33 executes a fourth data storage process (d) and stores the read data in the work memory 34.

The storage processing circuit 33 sets the current status ST1 as the previous status ST2 in step 62 after storing the read data in the main memory 15 or in the work memory 34.

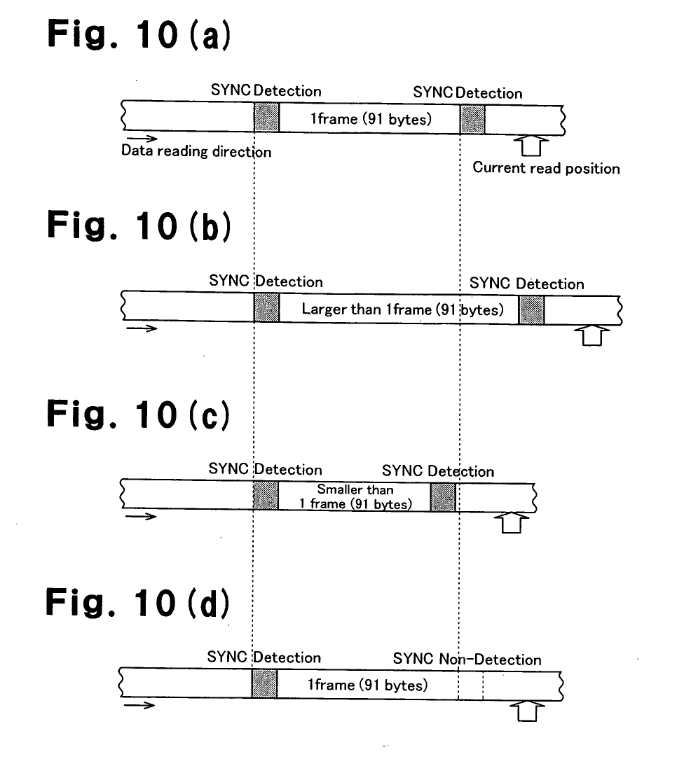

FIGS. 10(a), 10(b), 10(c), and 10(d) are schematic diagrams showing a reading operation performed when the status ST2 indicates the first status (SY_OK). In FIGS. 10(a), 10(b), 10(c), and 10(d), broken lines indicate expected positions at which sync codes are expected to be detected.

As shown in FIG. 10(a), when the current status ST1 indicates the first status, that is, when one frame (91 bytes) of read data exists between two sync codes, the storage processing circuit 33 performs the first storage process (a) to store the data in the main memory 15.

As shown in FIG. 10(b), when the current status ST1 indicates the second status, that is, when more than one frame of read data exists between the two sync codes, the storage processing circuit 33 performs the second storage process (b) to store data in the main memory 15.

As shown in FIG. 10(c), when the current status ST1 indicates the third status, that is, when less than one frame of read data exists between the two sync codes, the storage processing circuit 33 performs the third storage process (c) to store data in the main memory 15.

As shown in FIG. 10(d), when the current status ST1 indicates the fourth status, that is, when a sync code is not detected, the storage processing circuit 33 performs the fourth storage process (d) to temporarily store data following the previous sync code in the work memory 34.

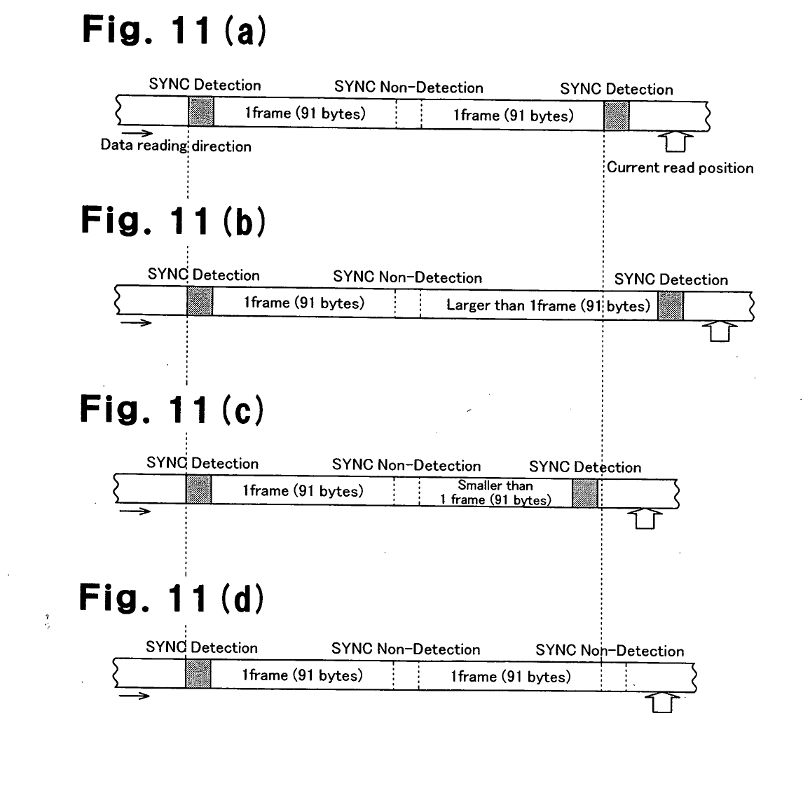

FIGS. 11(a), 11(b), l(c), and 11(d) are schematic diagrams of a reading operation performed when the status ST1 indicates the fourth status (SY_NOT), that is, when a sync code is undetected. In this case, one sync code is not detected. Thus, the code non-detection count Not_cnt is set at 1. The work memory 34 stores at least one frame of read data. In FIGS. 11(a), 11(b), 11(c), and 11(d), broken lines indicate positions at which sync codes are expected to be detected.

As shown in FIG. 11(a), when the current status ST1 indicates the first status, read data having a predetermined number of bytes (two frames of data in this case) and an undetected sync code are included between two sync codes. Thus, the storage processing circuit 33 stores the two frames of data in the work memory 34 at predetermined addresses in the main memory 15 based on the code non-detection count Not_cnt.

As shown in FIG. 11(b), when the current status ST1 indicates the second status, the storage processing circuit 33 stores one frame of read data, which is stored in the work memory 34, in the main memory 15 in accordance with the code non-detection count Not_cnt. More specifically, the storage processing circuit 33 stores the first frame of data adjacent to the preceding sync code sequentially from the first address of the predetermined memory space. Further, the storage processing circuit 33 stores the read data, which is larger than one frame and stored in the work memory 34, in the main memory 15 sequentially from the final data adjacent to the current sync code. When doing so, the storage processing circuit 33 sequentially stores the data from the final address of the predetermined memory space. The storage processing circuit 33 then deletes unnecessary data.

As shown in FIG. 11(c), when the current status ST1 indicates the third status, the storage processing circuit 33 stores one frame of read data, which is stored in the work memory 34, in the main memory 15 in accordance with the code non-detection count Not_cnt. More specifically, the storage processing circuit 33 stores the first frame of data adjacent to the preceding sync code sequentially from the first address of the predetermined memory space. Further, the storage processing circuit 33 sequentially stores the read data, which is smaller one frame and stored in the work memory 34, in the main memory 15 sequentially from the final data adjacent to the current sync code. When doing so, the storage processing circuit 33 stores the read data sequentially from the final address of the predetermined memory space. The storage processing circuit 33 then performs zero padding to compensate for the missing data.

As shown in FIG. 11(d), when the current status ST1 indicates the fourth status, the storage processing circuit 33 temporarily stores read data of the preceding frame in the work memory 34. In this state, the work memory 34 stores two frames of data.

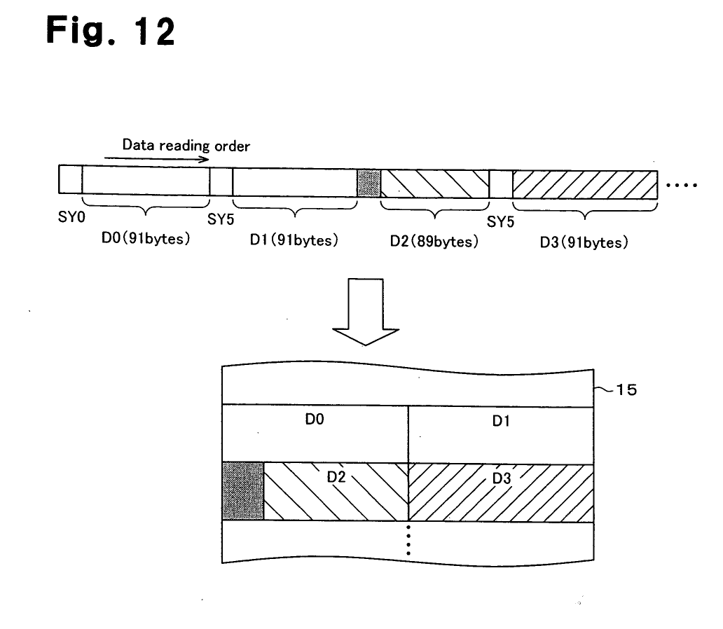

FIG. 12 is a schematic diagram showing a data storage operation corresponding to the reading operation of FIG. 11(c). Data D1 and D2 and an undetected sync code are included between two sync codes SY5. When the amount of data D2 is smaller than the specified amount, the data D2 is sequentially stored in a predetermined memory space of the main memory 15 from the last address in accordance with the byte number indicated by the byte count Byte_cnt. Zero padding is performed to add “0” to the head of the data D2.

In the preferred embodiment, when data of the first two bytes is missing in a frame, data of the remaining 89 bytes is stored at correct positions in the main memory 15. When data of two bytes in the middle of one frame is missing, the data following the missing two bytes up to the detected sync code is stored at correct positions in the main memory 15. Thus, the amount of data stored at correct positions is greater in the preferred embodiment than in the prior art example in which one frame of data is entirely stored at incorrect positions. As a result, the reading performance is higher in the present embodiment.

The reproduction device 10 of the preferred embodiment has the advantages described below.

(1) The detection circuit 31 detects a sync code included in read data. The analysis circuit 32 analyzes the read status of the detected sync code. The storage processing circuit 33 adjusts the storage position at which data segment between two sync codes is stored. As a result, the amount of data stored at correct positions increases. This improves the reading performance.

(2) The storage processing circuit 33 adjusts the number of bytes in the read data to a predetermined number (specified value) by adding dummy data to the read data when a sync code is detected at a position in front of an expected position of the sync code. The storage processing circuit 33 then stores the read data in the predetermined memory space based on at least one of the two sync codes through the first process (A1) of storing the read data from the head, the second process (A2) of storing the read data from the end, or the third process (A3) of combining the first and second processes. Even when, for example, irregular rotation of the optical disc causes the read data to be lost partially, the amount of data stored at correct positions (particularly at positions close to sync codes) increases. This improves the reading performance.

(3) The storage processing circuit 33 stores data having a predetermined number of bytes (specified value) in the main memory 15 through one of the first to third processes (A1), (A2), and (A3) based on at least one of the two sync codes when a sync code is detected at a position behind an expected position of the sync code. The storage processing circuit 33 deletes excessive data exceeding the predetermined number of bytes. Accordingly, when, for example, irregular rotation of an optical disc generates excessive data on the disc, the amount of data stored at correct positions (particularly at positions close to sync codes) increases. This improves the reading performance.

(4) The storage processing circuit 33 temporarily stores the read data in the work memory 34 when a sync code is not detected in a predetermined detection range. The storage processing circuit 33 then stores the read data, which is stored in the work memory 34, in the main memory 15 based on a sync code detected afterward and the code non-detection count Not_cnt. Accordingly, the amount of data stored at correct positions increases and the reading performance improves even when a sync code is not detected.

(5) The storage position of the data segment stored in the main memory 15 is adjusted. The adjustment reduces the amount of data that is determined as being an error during error correction. As a result, the reading performance is improved.

The amount of data stored is not limited to the predetermined number of bytes (91 bytes) as long as the storage position of data segment stored in the main memory 15 is adjusted.

The number of bytes of the sync code, the user data, and the correction code data P1 and the correction code data PO may be changed when necessary.

Although the eight-to-sixteen modulation and the eight-to-sixteen demodulation are performed as the modulation and demodulation processes, other modulation and demodulation processes may be performed.

The present examples and embodiments are to be considered as illustrative and not restrictive, and the invention is not to be limited to the details given herein, but may be modified within the scope and equivalence of the appended claims.

What is claimed is:

1. A reproduction device for retrieving read data including a plurality of sync codes and a plurality of data segments, which are arranged alternately with the sync codes, and for storing the data segments in a first memory in accordance with the sync codes, the reproduction device comprising:
a detection circuit for detecting each of the sync codes from the read data to generate a detection signal;
an analysis circuit, connected to the detection circuit, for analyzing a read status of each of the sync codes with the read data and the detection signal to generate an analysis signal; and
a storage processing circuit, connected to the analysis circuit, for retrieving one of the data segments between two consecutive sync codes with the read data and the analysis signal and adjusting a position at which the one of the data segments is stored in the first memory.

2. The reproduction device according to claim 1, wherein the analysis circuit counts the read data in response to the detection signal and analyzes the read status of each of the sync codes based on the counting.

3. The reproduction device according to claim 2, wherein:
the sync codes including a first sync code and a second sync code; and
the storage processing circuit adjusts the position at which the one of the data segments between the first and second sync codes, consecutively detected by the detection circuit, is stored in the first memory.

4. The reproduction device according to claim 3, wherein:
the data segments each have a predetermined number of bytes; and
the analysis circuit analyzes the read status of the second sync code by determining whether the second sync code has been detected at an expected position relative to the first sync code based on the counting of the read data, and
the read status of the second sync code is one of:
a first status indicating that the second sync code has been detected at the expected position, with the one of the data segments between the first and second sync codes having the predetermined number of bytes;
a second status indicating that the second sync code has been detected at a position differing from the expected position, with the one of the data segments between the first and second sync codes being larger than the predetermined number of bytes;
a third status indicating that the second sync code has been detected at a position differing from the expected position, with the one of the data segments between the first and second sync codes being smaller than the predetermined number of bytes;
a fourth status indicating that the second sync code has been undetected in a detection range including the expected position.

5. The reproduction device according to claim 4, wherein when the read status of the second sync code is the first status, the storage processing circuit directly stores the one of the data segments having the predetermined number of bytes in the first memory.

6. The reproduction device according to claim 4, wherein when the read status of the second sync code is the second status, the storage processing circuit:
stores the one of the data segments that is larger than the predetermined number of bytes in a predetermined memory space of the first memory by performing one of a first process for sequentially storing the one of the data segments from a data head adjacent to the first sync code, a second process for storing the one of the data segments sequentially from a data end adjacent to the second sync code, and a third process for combining the first process and the second process; and
deletes data that is non-storable in the predetermined memory space.

7. The reproduction device according to claim 4, wherein when the read status of the second sync code is the third status, the storage processing circuit:
stores the one of the data segments that is smaller than the predetermined number of bytes in a predetermined memory space of the first memory by performing one of a first process for storing the one of the data segments sequentially from a data head adjacent to the first sync code, a second process for storing the one of the data segments sequentially from a data end adjacent to the second sync code, and a third process for combining the first process and the second process; and
generates dummy data and stores the dummy data in the predetermined memory space to compensate for missing data.

8. The reproduction device according to claim 4, further comprising:
a second memory connected to the storage processing circuit, wherein when the read status of the second sync code is the fourth status, the storage processing circuit stores the one of the data segments having the predetermined number of bytes and following the first sync code in the second memory.

9. The reproduction device according to claim 8, wherein:
the predetermined number of bytes corresponds to one frame;
the analysis circuit counts the number of the frames of the data segments stored in the second memory and generates count information; and
the storage processing circuit stores one or more of the data segments, which are stored in the second memory, in the first memory in accordance with the count information.

10. The reproduction device according to claim 1, wherein the data segments are each modulated through a predetermined modulation process, the reproduction device further comprising:
a decoder circuit, connected to the first memory and the storage processing circuit, for demodulating each of the data segments by performing a demodulation process that is in correspondence with the predetermined modulation process.

11. The reproduction device according to claim 1, wherein one of the data segments corresponds to one frame, a predetermined number of frames forms a data block, and the data block includes user data and correction data for correcting a read error, and wherein the first memory stores the data segments for the predetermined number of frames of the data block, the reproduction device further comprising:
an error correction circuit, connected to the first memory, for reading the data segments for the predetermined number of frames from the first memory and correcting the read error based on the correction data.

12. A method for retrieving read data including plural a plurality of sync codes and a plurality of data segments, which are arranged alternately with the sync codes, with a reproduction device and for storing the data segments in a first memory in accordance with the sync codes, the method comprising:
detecting each of the sync codes from the read data to generate a detection signal;
generating an analysis signal by analyzing a read status of each of the sync codes with the read data and the detection signal; and
retrieving one of the data segments between two consecutive sync codes with the read data and the analysis signal and adjusting a position at which the one of the data segments is stored in the first memory.

13. The method according to claim 12, wherein said generating an analysis signal includes counting the read data in response to the detection signal and analyzing the read status of each of the sync codes based on the counting.

14. The method according to claim 13, wherein:
the sync codes including a first sync code and a second sync code; and
said adjusting a position at which the one of the data segments is stored includes adjusting the position at which the one of the data segments between the consecutively detected first and second sync codes is stored in the first memory.

15. The method according to claim 14, wherein:
the data segments each have a predetermined number of bytes; and
said generating an analysis signal includes analyzing the read status of the second sync code by determining whether the second sync code has been detected at an expected position relative to the first sync code based on the counting of the read data; and
the read status of the second sync code is one of:
a first status indicating that the second sync code has been detected at the expected position, with the one of the data segments between the first and second sync codes having the predetermined number of bytes;
a second status indicating that the second sync code has been detected at a position differing from the expected position, with the one of the data segments between the first and second sync codes being larger than the predetermined number of bytes;
a third status indicating that the second sync code has been detected at a position differing from the expected position, with the one of the data segments between the first and second sync codes being smaller than the predetermined number of bytes;
a fourth status indicating that the second sync code has been undetected in a detection range including the expected position.

16. The method according to claim 15, wherein said adjusting a position at which the one of the data segments is stored includes directly storing the one of the data segments having the predetermined number of bytes in the first memory when the read status of the second sync code is the first status.

17. The method according to claim 15, wherein said adjusting a position at which the one of the data segments is stored includes when the read status of the second sync code is the second status:
storing the one of the data segments that is larger than the predetermined number of bytes in a predetermined memory space of the first memory by performing one of a first process for sequentially storing the one of the data segments from a data head adjacent to the first sync code, a second process for storing the one of the data segments sequentially from a data end adjacent to the second sync code, and a third process for combining the first process and the second process; and
deleting data that is non-storable in the predetermined memory space.

18. The method according to claim 15, wherein said adjusting a position at which the one of the data segments is stored includes when the read status of the second sync code is the third status:
storing the one of the data segments that is smaller than the predetermined number of bytes in a predetermined memory space of the first memory by performing one of a first process for storing the one of the data segments sequentially from a data head adjacent to the first sync code, a second process for storing the one of the data segments sequentially from a data end adjacent to the second sync code, and a third process for combining the first process and the second process; and
generates dummy data and stores the dummy data in the predetermined memory space to compensate for missing data.

19. The method according to claim 15, wherein the reproduction device includes a second memory, and said adjusting a position at which the one of the data segments is stored includes:
storing the one of the data segments having the predetermined number of bytes and following the first sync code in the second memory when the read status of the second sync code is the fourth status.

20. The method according to claim 19, wherein:
the predetermined number of bytes corresponds to one frame;
said generating an analysis signal includes counting the number of the frames of the data segments stored in the second memory and generating count information; and
said adjusting a position at which the one of the data segments is stored includes storing one or more of the data segments, which are stored in the second memory, in the first memory in accordance with the count information.
